(19) United States
(12) Patent Application Publication
(10) Pub. No.: US 2014/0293722 A1
(43) Pub. Date: Oct. 2, 2014

(54) SEMICONDUCTOR STORAGE DEVICE AND SEMICONDUCTOR STORAGE DEVICE CONTROL METHOD

(71) Applicant: Fujitsu Limited, Kawasaki-shi (JP)

(72) Inventor: Takahiro AOYAGI, Foster City, CA (US)

(73) Assignee: FUJITSU LIMITED, Kawasaki (JP)

(21) Appl. No.: 14/307,632

(22) Filed: Jun. 18, 2014

Related U.S. Application Data
(63) Continuation of application No. PCT/JP2011/080482, filed on Dec. 28, 2011.

(51) Int. Cl. G11C 7/12

(52) U.S. Cl. CPC G11C 7/12
USPC 365/203

(57) ABSTRACT

When using a read circuit of a semiconductor memory device to read data in a memory cell through a bit line BLX, out of a bit line pair BL, BLX that have a complementary relationship to each other and are connected to the memory cell storing the data, control is performed by a discharge circuit disposed within the read circuit, based on the signal from the bit line BL and a signal indicating the memory cell, to prevent a rise in potential of an SOUT node of the read circuit, or to prevent a fall in potential of the SOUT node, according to the potentials of the bit line pair BL, BLX. The SOUT accordingly does not become a floating node, enabling reading malfunction due to leak current to be prevented and enabling increased reading speed.

### CROSS-REFERENCE TO RELATED APPLICATION

This application is a continuation application of International Application No. PCT/JP/2011/080482, filed Dec. 28, 2011, the disclosure of which is incorporated herein by reference in its entirety.

### FIELD

The embodiments discussed herein are related to a semiconductor storage device and a semiconductor storage device control method.

### BACKGROUND

Due to recent increases in the density of integration in semiconductor integrated circuits, integrated circuits such as System on Chips (SoC) are now being widely used, in which a microprocessor, such a Central Processing Unit (CPU), a memory, and peripheral circuits etc. are consolidated together onto a single chip. In such integrated circuits, there is a high proportion of surface area occupied by the memory relative to the total chip surface area, giving rise to issues regarding how to increase memory operation speeds and also achieve surface area reductions (savings in surface area). Moreover, there is increasing demand to increase operation speeds and achieve surface area reductions (savings in surface area) not only for memory in the form of memory microcells incorporated in an integrated circuit, but also for stand-alone memory.

Moreover, in integrated circuits such as those with two or more cores, so-called multi-core CPUs, acting as the computation processing section of computation circuits, product yield increases as the die size gets smaller. Reductions in the surface area occupied by primary cache memory and secondary cache memory incorporated in a multi-core CPU are accordingly beneficial for their effect on product yield.

FIG. 19 schematically illustrates a hierarchical structure of a memory circuit in a large scale integrated circuit for a single chip Central Processing Unit (CPU), peripheral circuits, memory etc. mounted on a single chip. As illustrated in FIG. 19, in a recent single chip integrated circuit 500, memory 501a to 501d occupies for example about 50 to 70% of the total surface area of the chip. The memory 501a to 501d are equipped with a plurality of respective memory circuits. Individual memory circuits (RAM macro) 510 also have a plurality of sub-arrays, control circuits and the like.

A sub-array 520, also referred to as a memory cell block, is a configuration element of a memory circuit 510, and is equipped with plural memory cell arrays. The memory cell arrays have memory cells at the intersection points of plural word lines and plural bit lines, connected together in a matrix pattern. FIG. 19 illustrates 1 columns worth of a memory cell array 530, and illustrates an example in which there are n+1 individual memory cells, and their read circuits, and write circuits in a two tiered configuration.

In a dynamic configuration read circuit for memory cells, a power source (VDD, or VSS) is not connected to a node, and there is an issue of malfunctioning occurring due to a micro-current flowing to the node in a floating state, or due to a micro-current flowing out from the node in a floating state. Hitherto, a keeper circuit has been disposed on the memory cell read circuit in order to prevent such malfunction. For example, in the following documents technology is disclosed wherein, in order to avoid malfunction due to leak current when a local bit line of a memory cell in static memory is in a floating state, a keeper circuit is disposed to maintain the local bit line at a specific potential. Usually, the keeper circuit is of a size to supply sufficient current to compensate for the leak current of the bit line, thereby functioning to maintain the voltage level of the bit line.

### RELATED PATENT DOCUMENTS

Japanese Patent Application Laid-Open (JP-A) No. 2010-198724

### SUMMARY

According to an aspect of the embodiments, a semiconductor storage device includes: a memory cell that stores data; a pair of bit lines connected to the memory cell; a read circuit that reads data in the memory cell via a first bit line out of the pair of bit lines; and a potential control circuit that, based on a signal from a second bit line out of the pair of bit lines and on a designation signal that designates the memory cell, effects control to prevent a rise in potential of an output terminal of the read circuit, or to prevent a fall in potential of the output terminal, in accordance with potentials of the first bit line and the second bit line.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a circuit diagram illustrating a configuration of a semiconductor storage device read circuit according to a first exemplary embodiment.

FIG. 2 is a timing chart of read operation in a read circuit according to the first exemplary embodiment (when CX=logical L).

FIG. 3 is a timing chart of read operation in a read circuit according to the first exemplary embodiment (when CX=logical H).

FIG. 4 is a diagram of a result of SPICE simulations performed on a read circuit according to the first exemplary embodiment and a related read circuit.

FIG. 5 is an explanatory diagram to illustrate the surface area reduction effect of a read circuit according to the first exemplary embodiment.

FIG. 6 is a diagram illustrating a schematic configuration of a sub-array of a semiconductor storage device according to a second exemplary embodiment.

FIG. 7 is a circuit diagram illustrating a detailed configuration of a read circuit of a sub-array according to the second exemplary embodiment.

FIG. 8 is a timing chart of read operation in a read circuit according to the second exemplary embodiment (when CX=logical L).

FIG. 9 is a timing chart of read operation in a read circuit according to the second exemplary embodiment (when CX is logical H).

FIG. 10 is an explanatory diagram to illustrate the surface area reduction effect of a read circuit according to the second exemplary embodiment.

FIG. 11 is a circuit diagram illustrating a detailed configuration of a read circuit of a sub-array in a semiconductor storage device according to a third exemplary embodiment. 80

FIG. 12A is a diagram of a discharge circuit according to the third exemplary embodiment.

FIG. 12B is a pattern layout diagram corresponding to a discharge circuit according to the third exemplary embodiment.

FIG. 13A is a diagram of a discharge circuit according to the second exemplary embodiment.

FIG. 13B is a pattern layout diagram corresponding to a discharge circuit according to the second exemplary embodiment.

FIG. 14 is a circuit diagram illustrating a configuration of a read circuit of a semiconductor storage device according to a fourth exemplary embodiment.

FIG. 15 is a timing chart of a read operation in a read circuit according to the fourth exemplary embodiment (when CX=logical L).

FIG. 16 is a timing chart of a read operation in a read circuit according to the fourth exemplary embodiment (when CX=logical H).

FIG. 17 is a diagram of an example of a read circuit in which a static circuit is employed.

FIG. 18 is an operation timing chart of a read circuit in which a static circuit is employed.

FIG. 19 is a schematic diagram of a hierarchical structure of a memory circuit in a large scale integrated circuit.

FIG. 20 is a circuit diagram illustrating an example of a read circuit of a memory cell in which a related dynamic circuit is employed.

FIG. 21 is a timing chart of read operation in a related read circuit (when CX=logical H).

FIG. 22 is a timing chart of read operation in a related read circuit (when CX=logical H).

### DESCRIPTION OF EMBODIMENTS

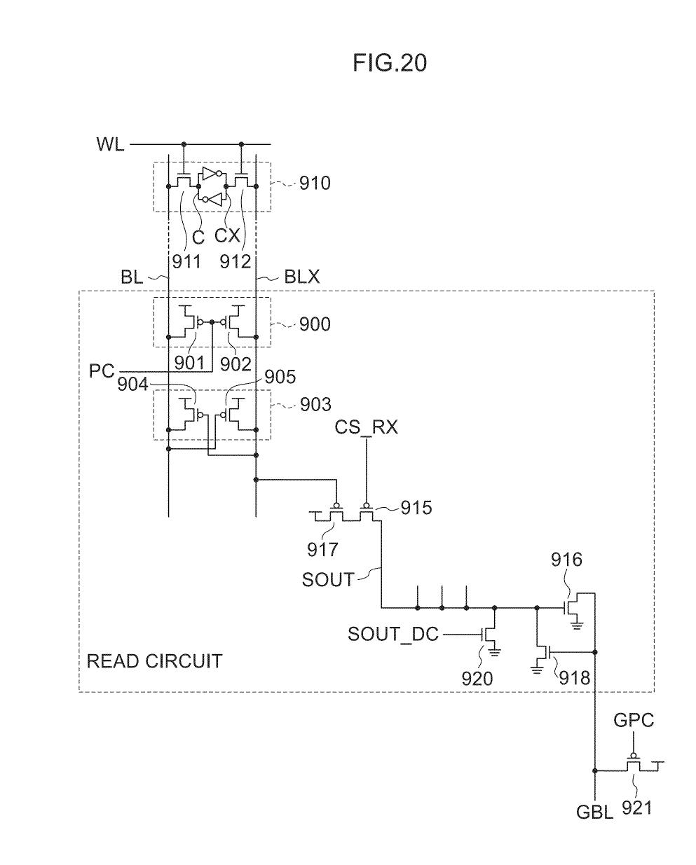

Explanation first follows regarding read circuits of memory cells. FIG. 20 is a circuit diagram illustrating an example of a read circuit of a memory cell that has employed a dynamic circuit. In a memory circuit with a single end configuration in which a MOS transistor is connected to a single bit line as a sense amplifier, increased speeds and reduced surface area reductions (savings in surface area) are pursued by using a dynamic circuit as a memory cell read circuit.

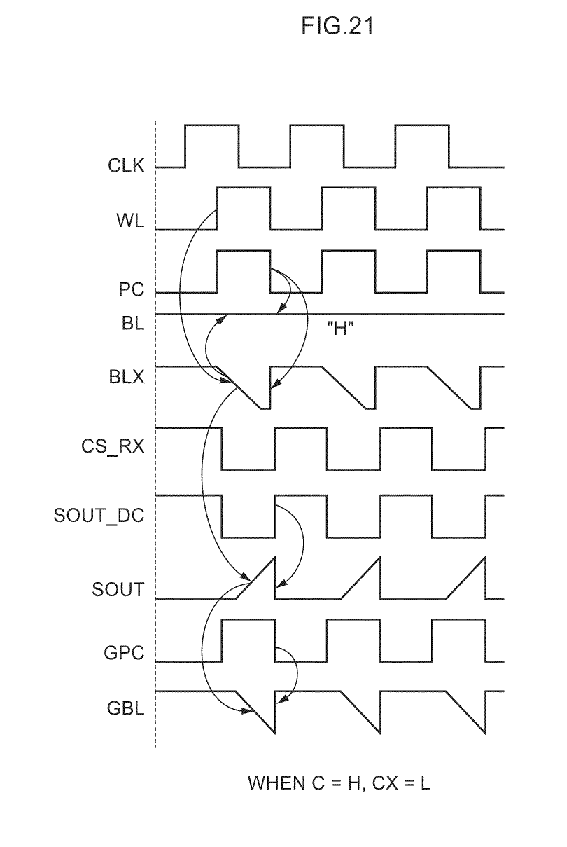

FIG. 21 is a timing chart of read operation in the read circuit illustrated in FIG. 20. In a read cycle, first a signal PC is applied at logical L of the same potential as VSS to gate terminals of the transistors 901, 902 of a pre-charge circuit 900, and logical H of the same potential as VDD is applied to the BL, BLX nodes of the bit line pair BL, BLX. Moreover, pre-discharging is performed by applying signal SOUT_DC at logical H to the SOUT discharge circuit 920, and by making the SOUT node logical L. Similarly, a signal GPC is applied at logical L to a pre-charge circuit 921 of GBL that is a global bit line, making the potential of the GBL logical H.

Regarding the signal PC, the signal SOUT_DC, and the signal GPC, as illustrated in FIG. 21, these are respectively made logical H, logical L, and logical H prior to the word line WL becoming logical H and the actual read operation taking place. Then, when the word line WL connected to a read target memory cell 910 is made logical H, the N-channel transistors 911, 912 of the memory cell 910 with gate terminals connected to the WL are switched ON.

Note that for multi-column memory circuit configurations, matching a read timing, the read target column selection signal CS_RX is made logical L, switching ON a column selection P-channel transistor 915. The column selection signal CS_RX for the non-read target columns is made logical H. The potential of the SOUT node is thereby determined by the potential of the BLX of the read target column.

If the CX node of the read target memory cell 910 is logical L, at the BLX node, charge is drawn out by that memory cell and the BLX node becomes logical L. Due to the gate terminal of a cell data reading P-channel transistor 917 being connected to the BLX node, the transistor 917 is switched ON. At this point, due to the column selection signal CS_RX of the read target column being logical L, as described above, charge flows into the SOUT node, and the potential of the SOUT node rises as illustrated in FIG. 21.

However, the BL node is fixed at logical H by a cross-coupling circuit 903 with a cross-coupling configuration including transistors 904, 905. This accordingly means that the potentials of the BL, BLX nodes have a complementary relationship (VDD, VSS) to each other during memory circuit read operation.

When the potential of the SOUT node rises as described above, the N-channel transistor 916 that draws charge from the GBL node is switched ON, and the GBL node potential becomes logical L. The potential of the GBL node is drawn into a latch circuit, not illustrated in the drawings, that is a read data latch connected to the GBL node, the potential of the GBL node is detected by the latch circuit, thereby completing memory cell reading.

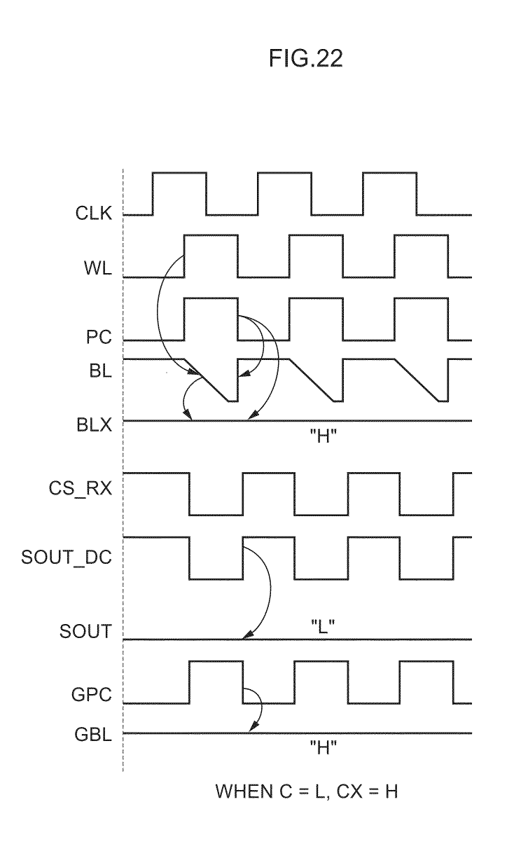

Note that when the CX node of the read target memory cell 910 is logical H, as illustrated in FIG. 22, charge is not drawn out from the BLX node, and charge is also not drawn out from the GBL node. As a result, when the CX node is logical L, potential data with the complementary relationship of logical H is drawn into the latch circuit, not illustrated in the drawings, that is a read data latch.

However, in the memory cell read circuit, the SOUT node of the dynamic circuit described above is a “floating node” that is not connected to a power source (the VDD or VSS). Hence a micro-current (also called leak current or latch current) arising from the transistors 915, 917 still flows at the floating node even when the transistors 915, 917 are OFF. A keeper circuit 918 is accordingly disposed on the SOUT node as a counter measure to such leak current.

When there is no keeper circuit 918 in a dynamic circuit, charge accumulates with time, and the potential of the SOUT node rises. For example, as illustrated in FIG. 22, if the BLX node is logical H, hitherto, even though the potential of the SOUT node does not rise, the potential rises due to leak current. If the floating node becomes an un-anticipated potential, then malfunction occurs due to leak current being drawn from the GBL node is by the N-channel transistor 916. Namely, due to the keeper circuit 918 being present at the floating node, charge flows from the VDD out to the VSS even when leak current occurs, and so the SOUT node potential does not rise.

Another problem, however, arises due to the presence of the keeper circuit 918 in the dynamic circuit. For example, if the potential of the SOUT node becomes higher than a threshold voltage Vth of the transistor 916, the keeper circuit 918 continues to draw the SOUT node until the transistor 916 has drawn the GBL. As a result, when the CX is logical L, and the SOUT is logical H, the SOUT node potential rise is delayed, leading to slower read speeds of data from memory cells.

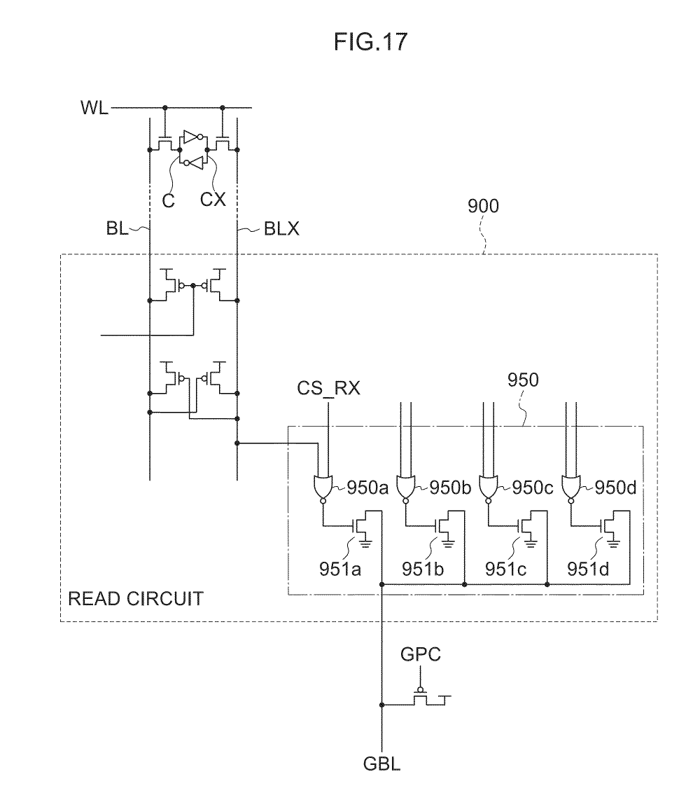

To address this configuration is made such that the SOUT node in the memory cell read circuit is not a “floating node”. Along with this, there is also consideration of a read circuit configuration that eliminates the keeper circuit that leads to delays in the rise in SOUT node potential and to slower read speeds. For example, employing a static circuit, such as the read circuit 900 illustrated in FIG. 17, enables malfunction to be avoided even when a keeper circuit is removed.

A static circuit 950 illustrated in FIG. 17 has a 4 column configuration, including 4 NOR circuits 950a to 950d, and 4 N-channel transistors 951a to 951d that are controlled by the respective outputs of these NOR circuits. Such a configuration needs the separately disposed N-channel transistors 951a to 951d to draw the GBL, and these transistors cannot be made common to plural columns Namely, an N-channel transistor is required for each of the columns to draw the GBL. In particular, due to there being many read circuits disposed in a memory circuit, increasing the number of N-channel transistors increases the surface area of the memory circuit overall. Moreover, due to the number of read circuits being proportional to the memory circuit storage capacity (to the number of memory cells), increasing the number of N-channel transistors has a larger effect the greater the storage capacity demanded by the memory circuit.

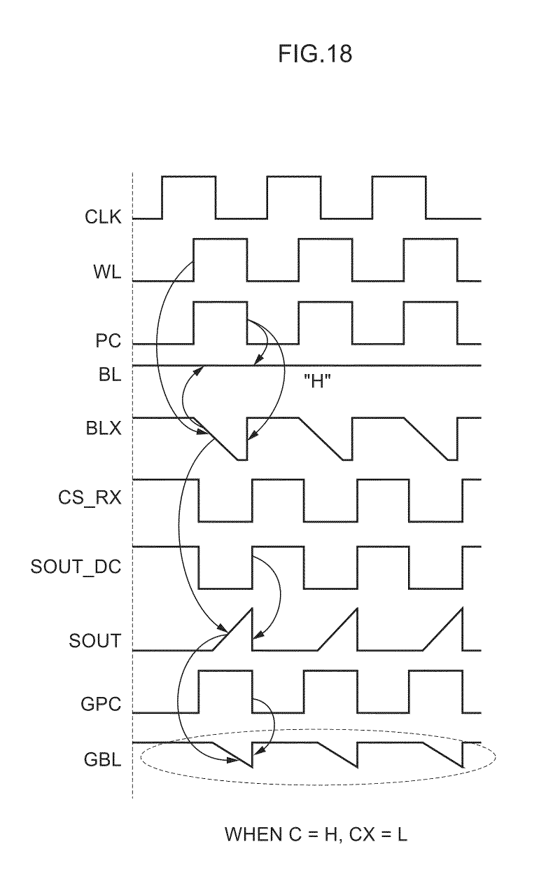

Moreover, the GBL nodes normally have a long wiring length, and so the N-channel transistors 951a to 951d that draw the GBL need to be large in size. The wiring length of the GBL node also lengthens due to the increase in the surface area of the memory circuit as described above. The capacity of the GBL increases due to the increase in the number of N-channel transistors connected to the GBL, and moreover the leak current amount drawn from the GBL increases due to the increase in the number of N-channel transistors connected to the GBL, and so the size of the keeper circuit (not illustrated in the drawings) for the GBL needs to be larger. Thus, as illustrated encircled with an intermittent line in timing chart of FIG. 18, the speed of drawing the charge of the GBL node becomes slower, and as a result the read speed is also slowed. These problems become more significant as the storage capacity of the memory circuit becomes larger.

Detailed explanation follows, with reference to the drawings, regarding a read circuit of a semiconductor storage device, regarding an exemplary embodiment of a read circuit that suppresses an increase in circuit surface area without using a static circuit, and is capable of high speed reading.

### First Exemplary Embodiment

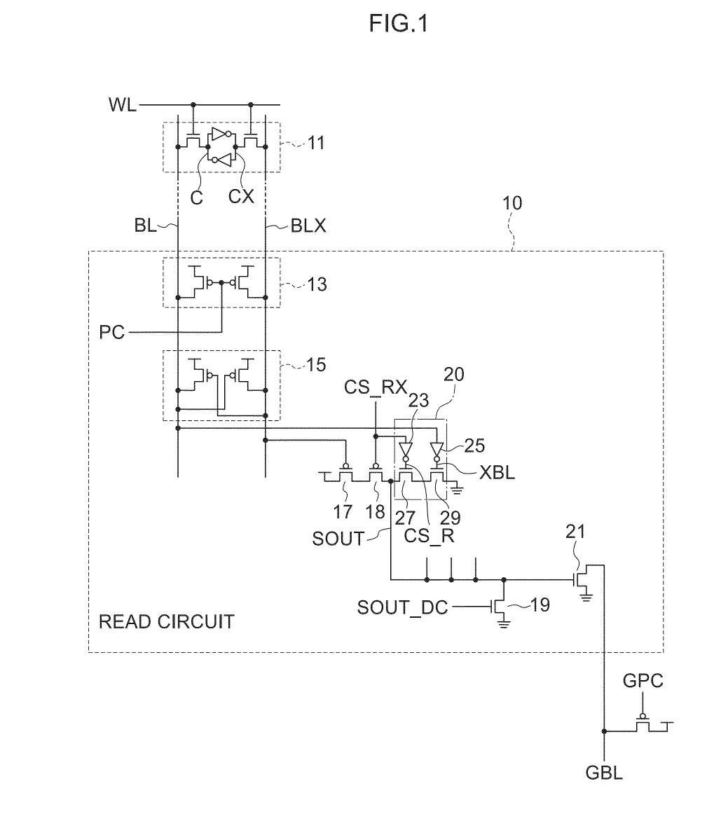

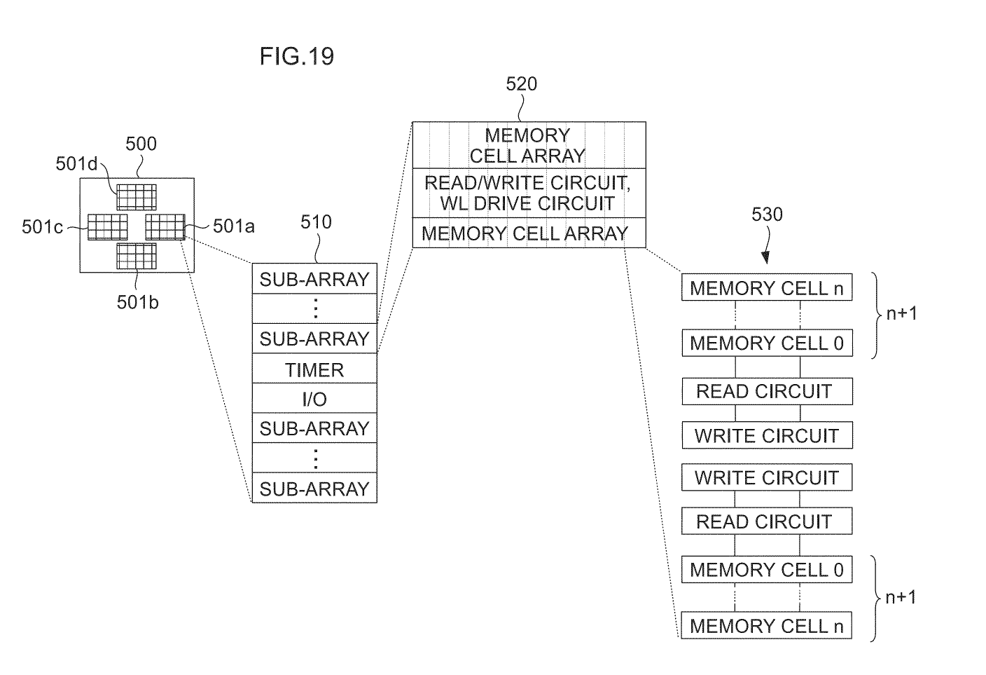

FIG. 1 is a circuit diagram illustrating a configuration of a read circuit of a semiconductor storage device according to the present exemplary embodiment. For example, although not illustrated in the drawings, the semiconductor storage device according to the present exemplary embodiment includes plural memory arrays equipped with plural memory cells that are disposed in a matrix pattern, and that have a memory cell configuration similar to the configuration illustrated in FIG. 19. In each of the memory cells, data is selected by word line WL selection, and output from the selected memory cell through bit line pairs BL, BLX that have a complementary relationship to each other.

A read circuit 10 of the semiconductor storage device at the present exemplary embodiment, in the example illustrated in FIG. 1, has a memory cell 11 connected to a word line WL as the read target memory cell, and includes a pre-charge circuit 13, a cross-coupling circuit 15, and a discharge circuit 20. The discharge circuit 20 discharges leakage current (leak current) from a cell data reading P-channel transistor 17 to an SOUT node, and from a column selection P-channel transistor 18 that selects a specific column from the plural memory cells. The read circuit illustrated in FIG. 1 has a 4 column configuration, and in FIG. 1 detailed configuration is illustrated for a single column thereof, with the configuration of the other columns omitted. The SOUT node is an output end of read data from a memory cell, and is common to the 4 columns, and provided with a discharge circuit 20 for each of the columns

The discharge circuit 20 is ON when the column selection signal CS_RX of the memory circuit has become logical level L and the signal level for the bit line BL out of the bit line pair BL, BLX of the read target column is logical L, and is OFF when the BL is logical H. Moreover, the column selection signal CS_RX is made logical H, and for non-read target columns the discharge circuits 20 are switched OFF, thereby avoiding operation of the non-read target columns affecting the potential of SOUT. Note that the column selection signal CS_RX is an example of the designation signal of the technology disclosed herein.

The discharge circuit 20 includes 2 inverter circuits 23, 25, and 2 N-channel transistors 27, 29 controlled by an output signal from these inverter circuits. The column selection signal CS_RX is input to the inverter circuit 23, and the logically inverted signal (also referred to as CS_R) of the CS_RX is input to the gate terminal of the N-channel transistor 27. The bit line BL is connected to the input terminal of the inverter circuit 25. As a result, a signal that is the logically inverted signal level of BL (also referred to as XBL) is input to the N-channel transistor 29.

The 2 N-channel transistors 27, 29 in the discharge circuit 20 are connected together in series, with the drain terminal of the N-channel transistor 27 connected to the SOUT node, and with the source terminal of the N-channel transistor 29 connected to VSS. The discharge circuit 20 is accordingly ON when the signal CS_R and the signal XBL are both logical H, such that current is discharged from the SOUT node to the VSS, as described later.

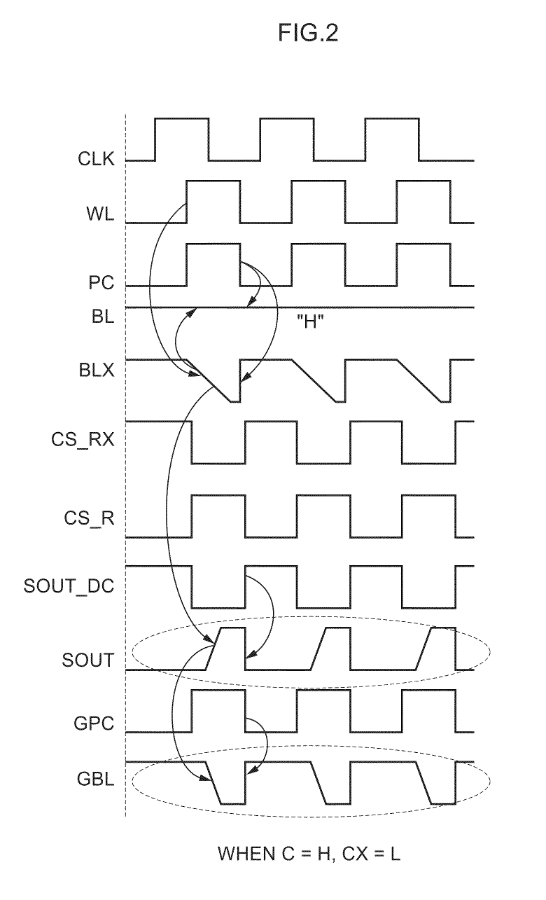

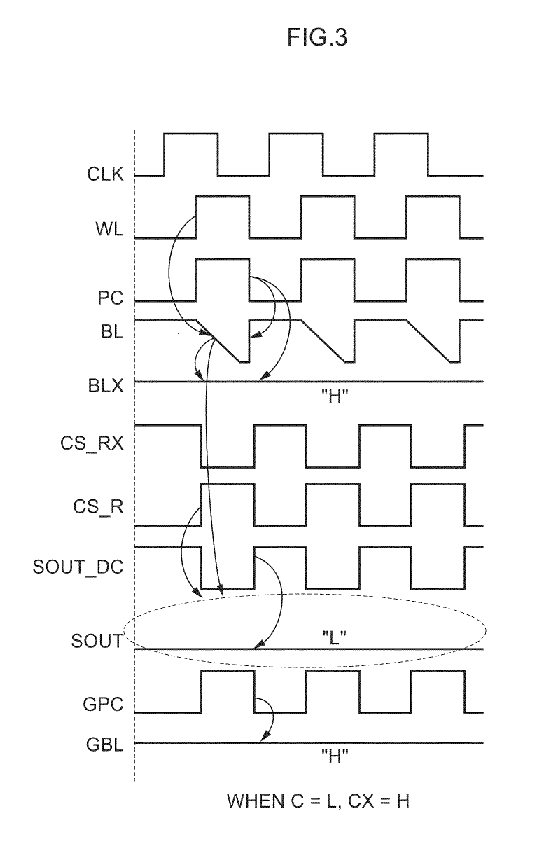

Detailed explanation next follows regarding operation of the discharge circuit 20, with reference to the timing chart of FIG. 2 and FIG. 3. Note that FIG. 2 illustrates a case in which a C node of a read target memory cell is logical H, and a CX node thereof is logical L. FIG. 3 corresponds to a case in which the C node of the read target memory cell is logical L, and the CX node is logical H.

Prior to starting the reading operation of the memory cell, the signal PC is made logical L, and the potentials of the BL, BLX nodes of the bit line pair BL, BLX are each made logical H. A signal SOUT_DC also becomes logical H, a discharge circuit 19 of the SOUT node is switched ON, and the SOUT becomes logical L. The signal GPC to pre-charge the GBL that is a global bit line is also made logical L, the making the GBL potential logical H. However, during read operation, the signal PC becomes logical H, and the BL, BLX nodes temporarily enter a floating state. When this occurs, since the signal SOUT_DC is logical L and the discharge circuit 19 is OFF, the SOUT node is also temporarily in a floating state.

When the CX node of the read target column memory cell is logical L, and the signal level of the C node having a complementary relationship to signal CX is logical H, as illustrated in FIG. 2, the BLX node is a logical L due to charge being drawn by the memory cell. When this occurs, the BL node is fixed to logical H by the cross-coupling circuit 15 of the read circuit 10. The cell data reading P-channel transistor 17 is switched ON by the logical L signal BLX, and charge is supplied from the VDD to the SOUT node through the P-channel transistor 17 that has been switched ON.

As described above, when the signal CS_RX is made logical L, the read target column is selected, and the signal level of the bit line BL of the read target column is logical H, the discharge circuit 20 is switched OFF due to the signal XBL becoming logical L. In such cases, that is nothing drawing charge from the SOUT node (namely there is nothing to prevent charge supply to the SOUT). Charge accordingly accumulates in the SOUT, and the SOUT node potential rises.

Regarding the SOUT node potential, a comparison of FIG. 2 and FIG. 21 illustrates that there is nothing preventing charge supply to the SOUT due to the read circuit of the present exemplary embodiment not having keeper circuit. Thus it is apparent that the time from when the SOUT potential rises to logical H is earlier than FIG. 21. As a result, drawing from the GBL is faster, enabling malfunction to be prevented, and speeding up data reading speed from the memory cells.

However, when the signal level of the CX node that has a complementary relationship to the signal level of the C node is logical H while the signal level of the C node of the memory cell in the reading target column is logical L, as illustrated in FIG. 3, charge is drawn from the BL node and so that it becomes logical L. When this occurs, the BLX node is fixed to logical H by the cross-coupling circuit 15. Since the cell data reading P-channel transistor 17 is OFF due to the signal BLX (logical H), charge is not supplied though the P-channel transistor 17 to the SOUT node. At this stage, leak current such as described above flows to the SOUT, however the signal CS_RX is logical L to select the read target column, and signal CS_R becomes logical H. When the signal level of the bit line BL of the read target column is logical L, the signal XBL becomes logical H. Since both the signal CS_R and the signal XBL then become logical H, the discharge circuit 20 is switched ON. The leak current to the SOUT accordingly flows to the VSS through the discharge circuit 20 (charge discharge), the SOUT node does not become a floating node, and as illustrated encircled with intermittent lines in FIG. 3, the potential of the SOUT does not rise.

Note that for non-read target columns, since the signal CS_R is logical L while the signal CS_RX is logical H, the discharge circuit 20 is switched OFF. The non-read target columns therefore do not contribute to a change in SOUT voltage. Configuration may also be made such that the signal CS_RX for circuits other than the read circuit 10 is logically inverted to generate the signal CS_R.

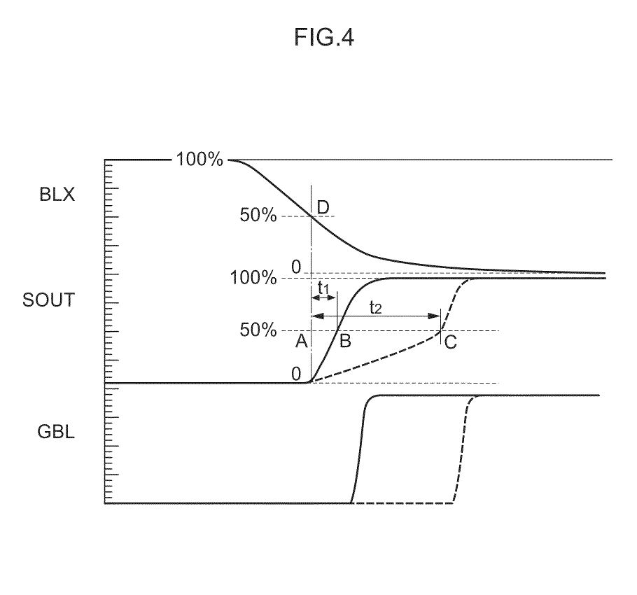

FIG. 4 illustrates read operation waveforms from SPICE simulations on the read circuit according to the present exemplary embodiment, and for a related read circuit. The simulation conditions are that the Vth for all of the transistors configuring the read circuit are standard values (typical), and a model extracted from layouts is used for the memory cell array, and a schematic model is used for the read circuit.

Respective SPICE simulation waveforms for signals BLX, SOUT, GBL are illustrated in FIG. 4, in sequence from top to bottom. In FIG. 4, the solid lines correspond to the read circuit according to the first exemplary embodiment, and the intermittent lines correspond to the related read circuit. The point D indicates here the point on the BLX wave form at 50% of the wave high value when charge is drawn by the memory cell and the BLX node transitions from logical H to logical L. The SOUT changes form logical L to logical H due to the potential change of the BLX.

As illustrated in FIG. 4, when the signal level of the BLX changes from logical H to logical L, point B indicates the point where the rise in SOUT is 50% of the wave high value in the read circuit according to the first exemplary embodiment, and point C indicates the point where 50% of the wave high in the related read circuit SOUT. Moreover, point A indicates the point corresponding to 50% of the SOUT wave high value on a vertical line descending through point D in FIG. 4. It is apparent from a comparison of time t1 indicated by segment AB, and time t2 indicated by segment AC, that t1 is about 20% of t2. Namely, it is apparent that the read circuit according to the present exemplary embodiment has, compared to the related read circuit, ameliorated about 80% of the delay to the SOUT node potential rising from drawing of the BLX. Stated in reverse, due to operation of the keeper circuit in the related read circuit, the time for the SOUT node potential to rise to a specific value takes about 5 times that of the read circuit according to the present exemplary embodiment.

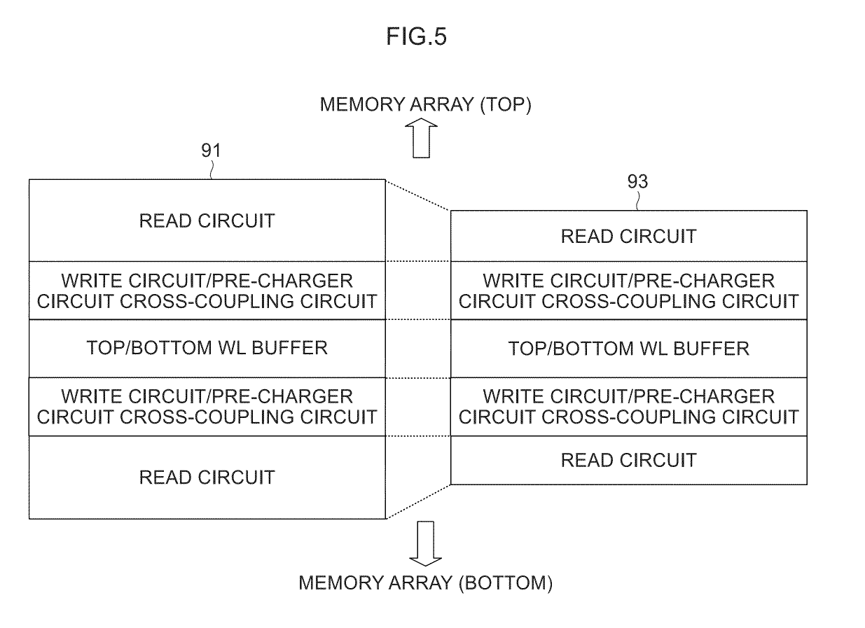

FIG. 5 is an explanatory diagram to illustrate the surface area reduction effect for the read circuit according to the present exemplary embodiment and for the related read circuit. The read circuit according to the present exemplary embodiment will now be compared to a read circuit of the static configuration described above. Taking into account that there is ¼ the number of N-channels transistors to draw the GBL, then compared to the related read circuit 91, the read circuit 93 according to the present exemplary embodiment has a reduction effect of about 20% in occupied surface area on a chip substrate.

Note that due to variation in the characteristics of transistors employed in related read circuits, the problem of significantly late rising of SOUT potential occurs when, for example, the operation speed of the P-channel transistors is slow and the operation speed of the N-channel transistors is fast. In an extreme case, the potential of the SOUT does not rise and malfunction occurs. This phenomenon occurs in particular when drawing of the BL, BLX by the memory cell is slower than other parts of the circuit, and so tends to occur in normal dynamic circuits. There is accordingly a need to adjust the transistor size during circuit design in consideration of this problem.

As explained above, in the present exemplary embodiment, a discharge circuit is disposed at the SOUT node of the memory cell read circuit. Then, during the data read operation by the read circuit, according to the signal level of the bit line pairs BL, BLX that have a complementary relationship to each other, the discharge circuit is switched OFF by the signal from bit lines BL not being user for data reading. By switching the discharge circuit OFF, the charge to the SOUT node is maintained at the SOUT potential. By switching the discharge circuit ON during data read operation, the charge from the SOUT node is discharged to the ground connection terminal of the discharge circuit, preventing the SOUT potential from rising. Adopting such a configuration enables the SOUT of the read circuit to be prevented from becoming a floating node, making a keeper circuit redundant, enabling reading malfunction due to leak current to be prevented, and enabling the read operation to be made faster.

Namely, by providing the discharge circuit to the SOUT node, and by using the BL node potential to control the transistors within the discharge circuit that draws the S OUT, the capacity of the BLX that determines the read speed of the read circuit is not increased, so as not to cause a deterioration in read speed of the discharge circuit.

Moreover, even without a keeper circuit, since it is possible to make the read circuit common to plural columns, the occupied surface area on a semiconductor substrate can be made smaller than a read circuit of static configuration.

### Second Exemplary Embodiment

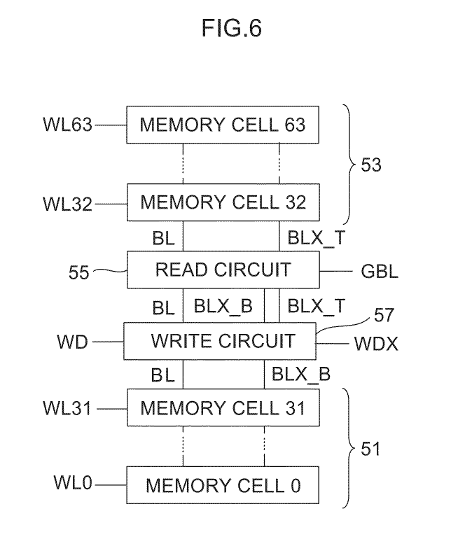

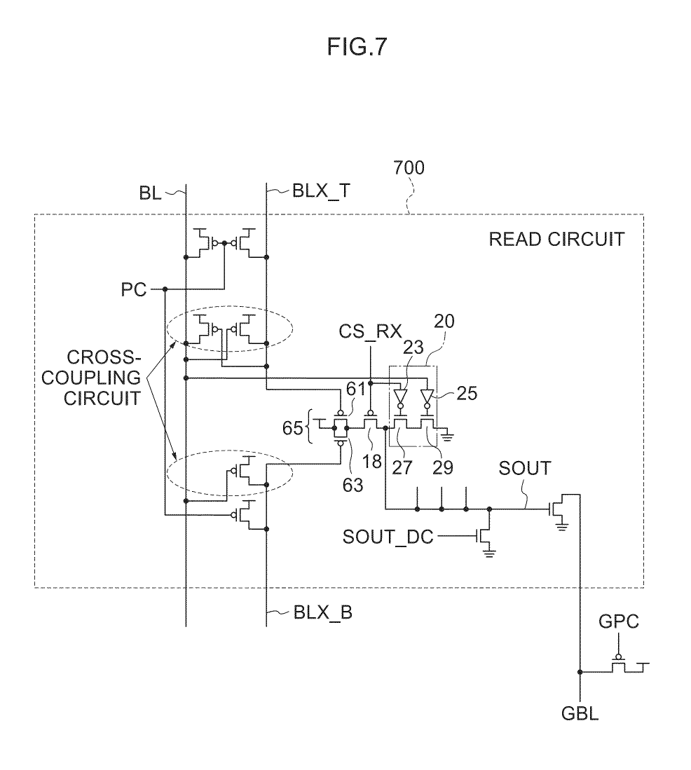

FIG. 6 is a circuit diagram illustrating a schematic configuration of a sub-array of a semiconductor storage device according to a second exemplary embodiment. FIG. 7 is a circuit diagram illustrating a detailed configuration of a sub-array read circuit. Note that in a read circuit 700 illustrated in FIG. 7, the same reference numerals are allocated to similar configuration elements to those of the discharge circuit illustrated in FIG. 1. The sub-array illustrated in FIG. 6 is equipped with plural (64 in this case) cell arrays that are divided into two: a first cell array 51 equipped with 32 memory cells 0 to 31; and a second cell array 53 that is similarly equipped with 32 memory cells 32 to 63. A read circuit 55 is then disposed commonly to the first cell array 51 and the second cell array 53.

In the sub-array according to the present exemplary embodiment, as illustrated in FIG. 6, bit lines BL that are not being used during memory cell reading are common to both the first cell array and the second cell array. However, bit line BLX_T, BLX_B that are used in reading memory cells are, as illustrated in FIG. 7, connected in parallel to the SOUT node. Then the signal level of either the bit line BLX_T or the BLX_B is made logical L, switching ON a transformer 65 that includes the 2 individual P-channel transistors 61, 63. Furthermore, a read target column selection signal CS_RX becomes logical L, and a transistor 18 is switched ON, and the discharge circuit 20 is switched OFF. As a result, charge flow from the VDD into the SOUT.

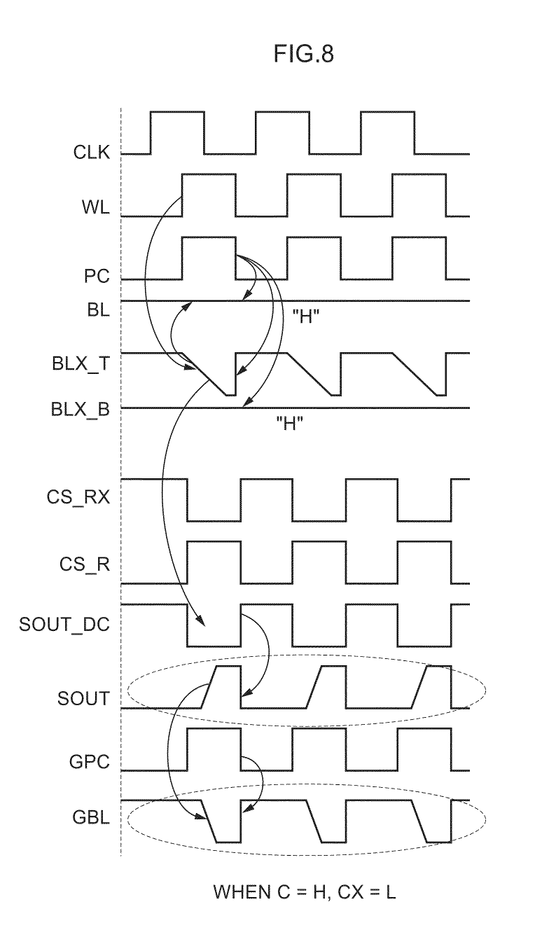

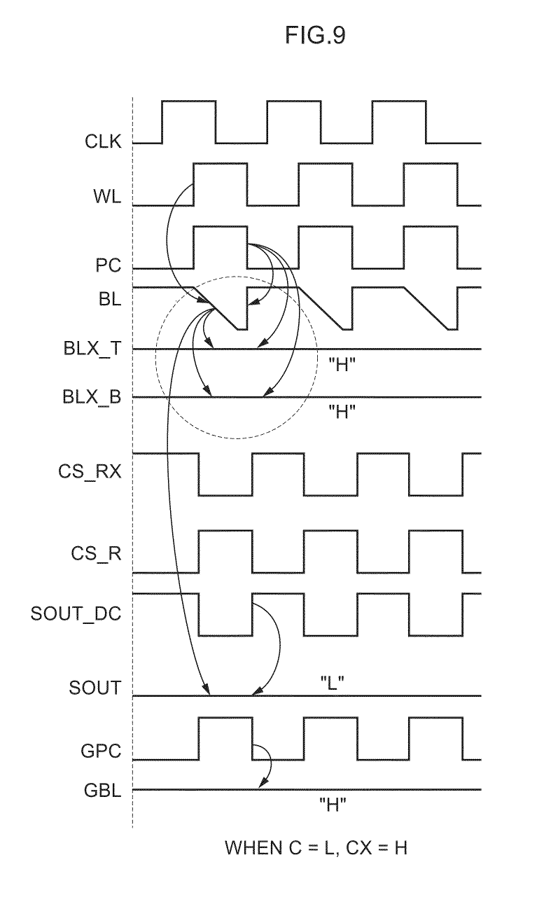

FIG. 8 is an operation timing chart for a sub-array according to the present exemplary embodiment, in a case in which the C node is logical H, the CX node is logical L. FIG. 9 is an operation timing chart for a case in which the C node is logical level L, and the CX node is logical H. FIG. 8 is an operation timing chart for a case in which a memory cell connected to a bit line BLX_T (omitted in FIG. 7) is the read target. However, since the word line WL of the non-read target memory cells is logical L, as illustrated in FIG. 8, the bit line BLX_B is not drawn by the memory cell.

It is conceivable that, when the BLX_T is logical L during read operation (the potential of the BLX_B does not fall when the BL is logical L, due to the cross-coupling circuit), the potential of the bit line BLX_B falls due to leak current. However, in such cases, not only is the ON current of the transistors of the memory cell also switched ON by the leak current, but also the bit line BLX_T is already drawn by the memory cell, and so the SOUT node becomes logical H. Thus malfunction due to leak current does not occur.

Note that read operation is also similar to the above for cells connected to the bit line BLX_B as the read target memory cells.

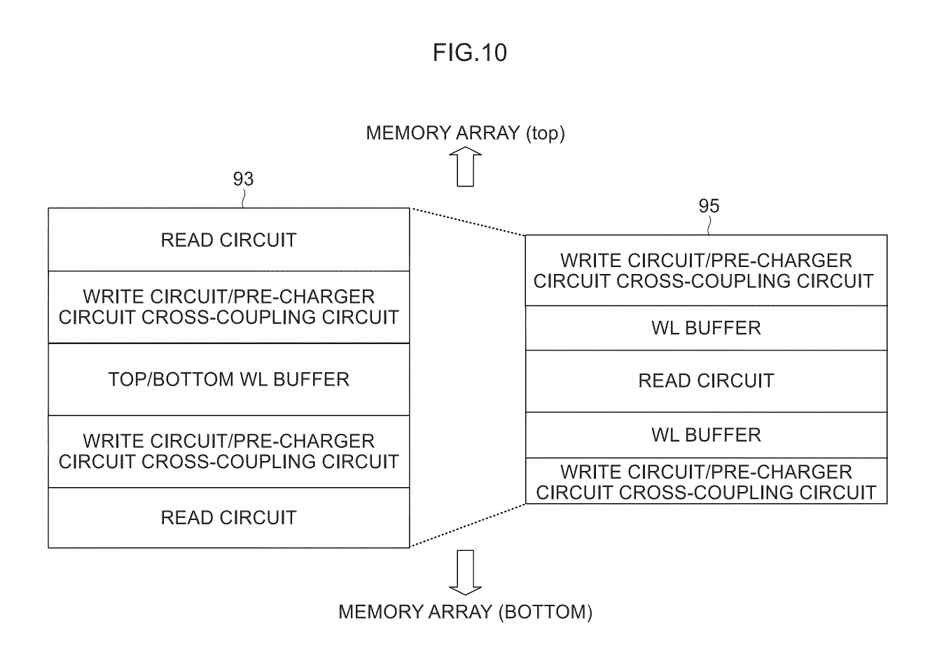

FIG. 10 is an explanatory diagram to explain the surface area reduction effect of the present exemplary embodiment. In the present exemplary embodiment, the memory cell read circuits are common to the first cell array and the second cell array. Adopting such an approach enables, as illustrated in FIG. 10, the occupied surface area on a chip substrate for a read circuit 95 according to the present exemplary embodiment to be reduced by about 10%, in comparison to a read circuit 93 of the first exemplary embodiment.

Thus, in the present exemplary embodiment, the plural cell arrays are divided into the first cell array and the second cell array, and the read circuit is disposed commonly to both the first cell array and the second cell array. Adopting such an approach enables a reduction in surface area (saving in surface area) of the read circuit, to be achieved.

### Third Exemplary Embodiment

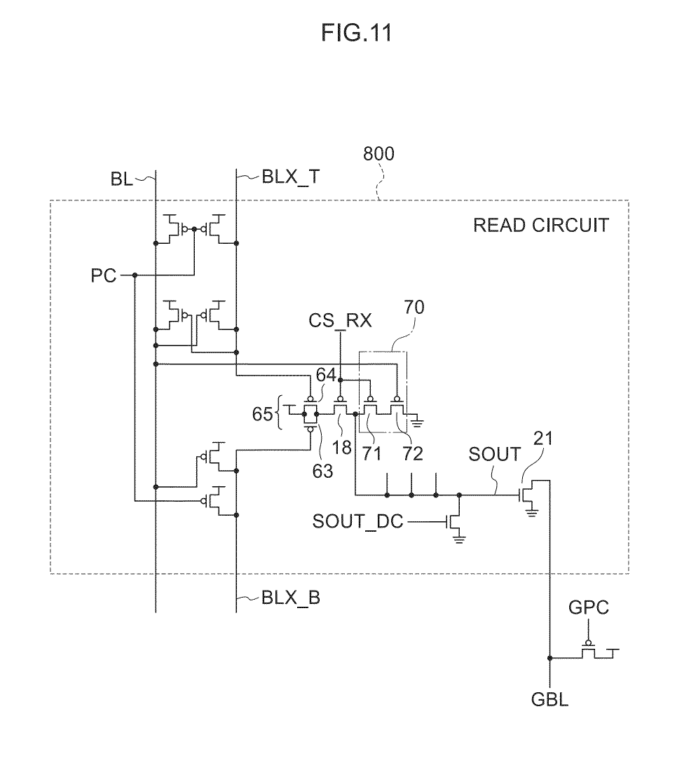

FIG. 11 is a circuit diagram illustrating a detailed configuration of a read circuit of a sub-array according to a semiconductor storage device according to a third exemplary embodiment. In a read circuit 800 as illustrated in FIG. 11, as described above, the same reference numerals are allocated to similar configuration to the read circuit of the sub-array according to the second exemplary embodiment illustrated in FIG. 7.

As illustrated in FIG. 11, a discharge circuit 70 of a read circuit according to the present exemplary embodiment includes 2 P-channel transistors, namely a transistor 72 that is connected a bit line BL, and a transistor 71 that is connected to a column selection signal CS_RX. In the read circuit according to the present exemplary embodiment, the threshold voltage Vth is set low for the above transistors 71, 72, and of 3 P-channel transistors 18, 63, 64 that supply charge to a SOUT node (these transistors are also referred to as low threshold (Lvt) transistors). Moreover, in a read circuit according to the present exemplary embodiment, the threshold voltage Vth is set high for a N-channel transistor 21 that draws the GBL when the SOUT node potential has risen (such transistors are also referred to as high threshold (Hvt) transistors).

In the read circuit illustrated in FIG. 11, as described above, the transistors 71, 72 of the discharge circuit 70 that draws the SOUT are low threshold (Lvt) transistors. Thus when the discharge circuit 70 is switched ON, the threshold voltage Vth of the N-channel transistor 21 that draws the GBL is high even if potential of the amount of the threshold voltage Vth fall of the transistor remains in the SOUT, and so the transistor 21 is not switched ON. The GBL is accordingly not drawn, and malfunction does not occur.

Note that even suppose, hypotheticaly, the transistor 21 was slightly ON, the keeper circuit connected to the GBL (not illustrated in FIG. 11) would operate, such that drawing from the GBL does not occur.

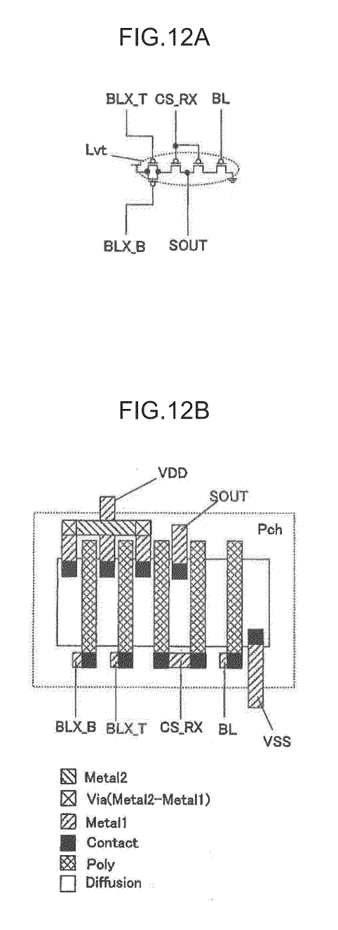

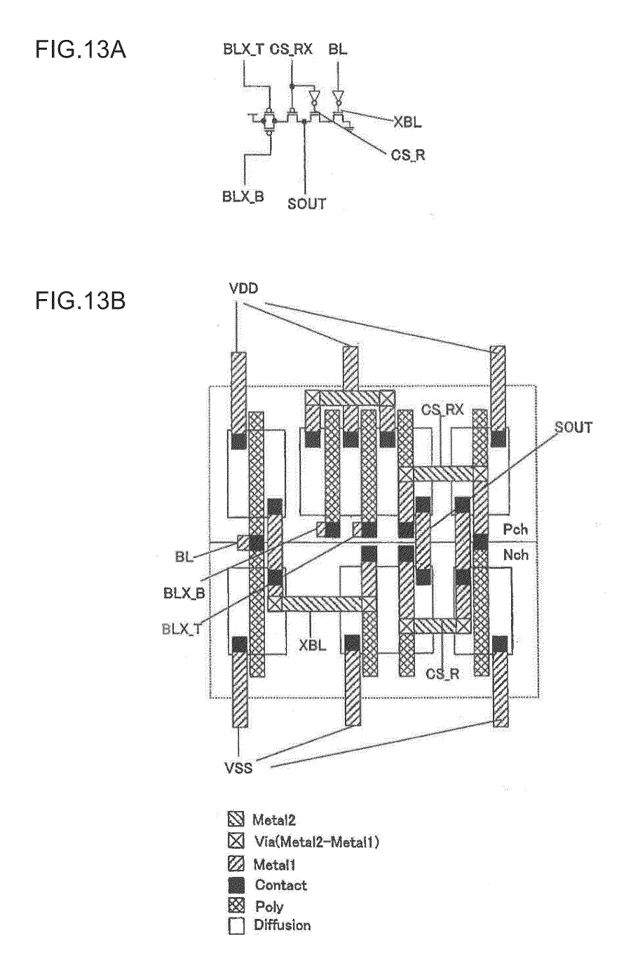

FIG. 12A illustrates the transistors 71, 72 of the above described discharge circuit 70, the P-channel transistors 18, 61, 63 that supply charge to the SOUT node, applied with an input signal. Moreover, FIG. 12B is a pattern layout corresponding to the circuit configuration illustrated in FIG. 12A. FIG. 13B is a pattern layout corresponding to a circuit illustrated in FIG. 13A, including the discharge circuit according to the second exemplary embodiment, and the transistors connected thereto, as illustrated in FIG. 13A.

In the third exemplary embodiment, the pattern of the inverter circuit has been eliminated from the read circuit according to the second exemplary embodiment illustrated in FIG. 13B. Moreover, in the third exemplary embodiment, the P-channel transistors within the discharge circuit, and the P-channel transistors that supply charge to the SOUT node are all configured from Lvt transistors. As a result, as illustrated in FIG. 12B, the read circuit according to the third exemplary embodiment enables a reduction of about 10% in surface area, compared to the circuit according to the second exemplary embodiment.

As explained above, in the third exemplary embodiment, in comparison to the read circuit according to the second exemplary embodiment, the inverter circuit to generate the CS_R, XBL becomes redundant. The transistor diffusion region can be made common by making all of the P-channel transistors within the discharge circuit, and the P-channel transistors that supply charge to the SOUT node, Lvt transistors. Namely, since it is possible to construct a layout with common sources and drains, this thereby enables a smaller surface area (surface area reduction) to be achieved for the read circuit, a write circuit, and a WL drive circuit.

### Fourth Exemplary Embodiment

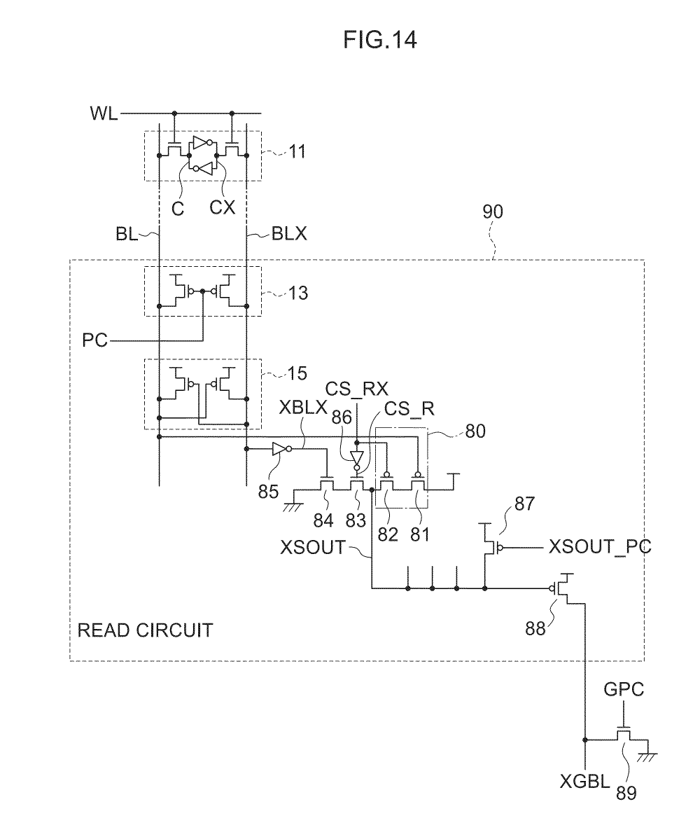

FIG. 14 is a circuit diagram illustrating a configuration of a read circuit of a semiconductor storage device according to the fourth exemplary embodiment. A read circuit 90 according to the present exemplary embodiment has a 4 column configuration, and a detailed configuration of one column thereof is illustrated in FIG. 14. An XSOUT node is common to all 4 columns, and each column is provided with a charge circuit 80, described later.

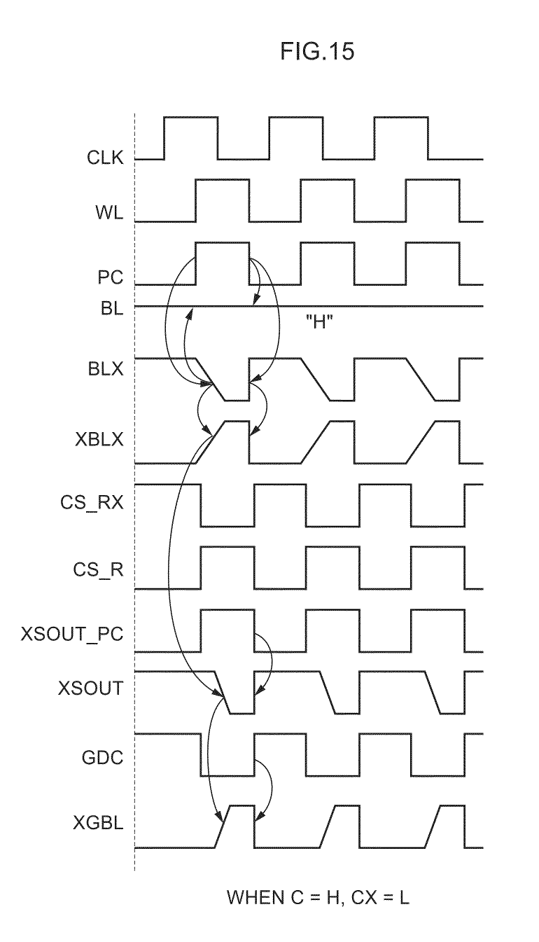

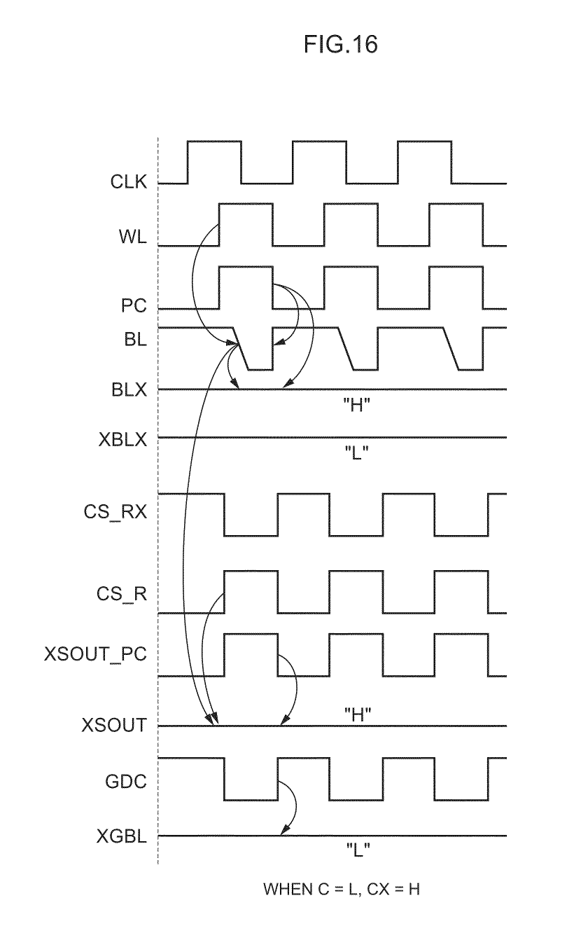

Detailed explanation next follows regarding operation of the charge circuit 80, with reference to the timing charts of FIG. 15 and FIG. 16. Note that FIG. 15 illustrates a case in which a signal level of a C node of a read target memory cell is logical H, and a signal level of a CX node is logical L. FIG. 16 illustrates a case in which the signal level of the C node of a read target memory cell is logical L, and the signal level of the CX node is logical H.

As illustrated in FIG. 14, the charge circuit 80 of the read circuit 90 includes 2 P-channel transistors 81, 82 that are connected together in series, with the source electrode of the transistor 81 connected to VDD, and the output terminal (the drain electrode) of the transistor 82 connected to the XSOUT node. A column selection signal CS_RX is input to the gate terminal of the transistor 82, and the signal for bit line BL that is not employed for memory cell reading is input to the gate terminal of the transistor 81.

Prior to starting read operation of the memory cell, a signal PC is made logical L, and the potential of the BL, BLX nodes of the bit line pair BL, BLX are all made logical H. Prior to read operation, a signal XSOUT_PC is made logical L, and in order to switch ON a transistor 87, the XSOUT node is made logical H. In order to pre-charge XGBL, this being a global bit line, signal GPC is made logical L, and the potential of the XGBL is made logical H. However, during read operation, a signal PC is made logical H, and the BL, BLX nodes are temporarily in a floating state.

During read operation, the column selection signal CS_RX for read target column becomes logical L, and the signal CS_R becomes logical H. At this stage, if the CX node of the read target column is logical L, then, as illustrated in FIG. 15, charge is drawn by the memory cell, and the signal level of the bit line BLX becomes logical L. A signal XBLX that is the signal BLX logically inverted by an inverter circuit 85 becomes logical H. Thus the signals CS_R, XBLX both become logical H, thereby switching the transistors 83, 84 ON, discharging charge to the VSS, and making the XSOUT logical L.

Since there is no keeper circuit in the read circuit illustrated in FIG. 14, discharge to the XSOUT is not prevented. Thus, as illustrated in FIG. 15, the potential fall of the XSOUT is rapid. When this occurs, the signal C that has a complementary relationship to the signal CX of the memory cells is logical H, and a BL node is fixed to logical H by a cross-coupling circuit 15. The signal level of the BL is logical H, and hence the charge circuit 80 is switched OFF.

However, when the signal CX of the read target column is logical H, as illustrated in FIG. 16, the BL signal level becomes logical L, the BLX signal level becomes logical H. Due to the BLX signal level being logical H, the signal XBLX is logical L, and the transistor 84 between the XSOUT node and the VSS is switched OFF. Thus charge of the XSOUT is not discharged. When this occurs, due to the signal levels of both the BL and CS_RX being logical L, the charge circuit 80 is switched ON, and charge is supplied from the VDD to the XSOUT node. In such cases, since XSOUT node does not become a floating node, the potential of the XSOUT node does not fall due to leak current.

Note that during read operation, the column selection signal CS_RX for the non-read target columns becomes logical H, the CS_R that is the output signal of an inverter 86 becomes logical L, and the transistor 83 is switched OFF. Due to the signal CS_RX being logical H, the transistor 82 of the charge circuit 80 is switched OFF, and the charge circuit 80 is also switched OFF. Thus in such cases the non-read target columns do not contribute to a voltage change in the XSOUT.

Thus in the present exemplary embodiment, a charge circuit is disposed at the XSOUT node of the memory cell read circuit. Then during read operation of the read circuit, the charge circuit is switched OFF by a signal of the bit line BL that is not employed to read data according to the signal levels of the bit line pair BL, BLX that have a complementary relationship to each other. Charge is accordingly discharged from the XSOUT node to the ground terminal through the transistors connected to the XSOUT node, thereby preventing the SOUT potential from rising. Moreover, during read operation of the read circuit, the charge circuit is switched ON by the signal of the bit line BL that is not employed for reading, thereby preventing XSOUT potential from falling. Since this thereby enables the XSOUT to be prevented from becoming a floating node, a keeper circuit becomes redundant, enabling read malfunction due to leak current to be prevented, and enabling increased speed in read operation.

Note that in each of the above exemplary embodiments, the memory circuits have single end configurations, however there is no limitation thereto, and for example a differential configuration may be employed.

Technology disclosed herein disposes a potential control circuit such as a discharge circuit on an output node of a memory cell read circuit. The potential control circuit is then controlled by the node potential of the bit line, from the bit line pair, that is not employed in reading of data from the memory cells, and preventing the data output terminal node from becoming a floating node. The technology disclosed herein is accordingly applicable not only to semiconductor memory circuits, but also to internal memory, cache memory, and working memory of semiconductor integrated circuits such as system LSIs or microprocessors.

According to an aspect, increased speed of data reading from memory cells is enabled.

All cited documents, patent applications and technical standards mentioned in the present specification are incorporated by reference in the present specification to the same extent as if the individual cited document, patent application, or technical standard was specifically and individually indicated to be incorporated by reference.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor storage device, comprising:
a memory cell that stores data;
a pair of bit lines connected to the memory cell;
a read circuit that reads data in the memory cell via a first bit line out of the pair of bit lines; and
a potential control circuit that, based on a signal from a second bit line out of the pair of bit lines and on a designation signal that designates the memory cell, effects control to prevent a rise in potential of an output terminal of the read circuit, or to prevent a fall in potential of the output terminal, in accordance with potentials of the first bit line and the second bit line.

2. The semiconductor storage device of claim 1, wherein:
when the first bit line is a first potential and the second bit line is a second potential that is higher than the first potential, the potential control circuit effects control so that current is output to the output terminal and the output terminal becomes the second potential; and
when the first bit line is the second potential and the second bit line is the first potential, the potential control circuit effects control so that current is output from the output terminal and the output terminal becomes the first potential.

3. The semiconductor storage device of claim 2, wherein the potential control circuit is a discharge circuit including, connected in series, a first transistor that is switched ON or OFF based on a signal of the second bit line, and a second transistor that is switched ON or OFF based on a signal that designates the memory cell.

4. The semiconductor storage device of claim 3, wherein:
when the first transistor and the second transistor are ON, current is output from the output terminal to a ground terminal of the first transistor through the second transistor; and
when the first transistor is OFF, current is output from a power source to the output terminal through a third transistor that is connected to the output terminal.

5. The semiconductor storage device of claim 1, wherein:
when the first bit line is a first potential and the second bit line is a second potential that is higher than the first potential, the potential control circuit effects control so that current is output from the output terminal and the output terminal becomes the first potential; and
when the first bit line is the second potential and the second bit line is the first potential, the potential control circuit effects control so that current is output to the output terminal and the output terminal becomes the second potential.

6. The semiconductor storage device of claim 5, wherein the potential control circuit is a charge circuit including, connected in series, a fourth transistor that is switched ON or OFF based on a signal of the second bit line, and a fifth transistor that is switched ON or OFF based on a signal that designates the memory cell.

7. The semiconductor storage device of claim 6, wherein:
when the fourth transistor and the fifth transistor are ON, current is output from a power source to the output terminal through the fourth transistor and the fifth transistor; and
when the fourth transistor is OFF, current is output from the output terminal through a sixth transistor that is connected to the output terminal, to a ground terminal of the sixth transistor.

8. The semiconductor storage device of claim 1, wherein the potential of the first bit line and the potential of the second bit line have a complementary relationship to each other, and the second bit line is not employed to read data from the memory cell.

9. The semiconductor storage device of claim 1, wherein:
the semiconductor storage device comprises a plurality of the memory cells, the pairs of bit lines, the read circuits and the potential control circuits;
the respective output terminals of the plurality of read circuits are connected together;
a selection signal is input as the designation signal to a read target memory cell out of the plurality of memory cells, and the potential control circuits corresponding to the memory cells other than the read target are switched OFF.

10. The semiconductor storage device of claim 9, wherein the plurality of memory cells includes a first plurality of memory cells and a second plurality of memory cells, and each of the plurality of the read circuits is commonly disposed for the first plurality of memory cells and the second plurality of memory cells.

11. A semiconductor storage device control method for a semiconductor storage device that includes a memory cell that stores data and a pair of bit lines connected to the memory cell, the control method comprising:
a read circuit of the semiconductor storage device reading data in the memory cell via a first bit line out of the pair of bit lines; and
a potential control circuit of the semiconductor storage device, based on a signal from a second bit line out of the pair of bit lines and on a designation signal that designates the memory cell, effecting control to prevent a rise in potential of an output terminal of the read circuit, or to prevent a fall in potential of the output terminal, in accordance with potentials of the first bit line and the second bit line.

12. The semiconductor storage device control method of claim 11, wherein:
when the first bit line is a first potential and the second bit line is a second potential that is higher than the first potential, the potential control circuit effects control so that current is output to the output terminal and the output terminal becomes the second potential; and
when the first bit line is the second potential and the second bit line is the first potential, the potential control circuit effects control so that current is output from the output terminal and the output terminal becomes the first potential.

13. The semiconductor storage device control method of claim 11, wherein:
when the first bit line is a first potential and the second bit line is a second potential that is higher than the first potential, the potential control circuit effects control so that current is output from the output terminal and the output terminal becomes the first potential; and
when the first bit line is the second potential and the second bit line is the first potential, the potential control circuit effects control so that current is output to the output terminal and the output terminal becomes the second potential.
